(19) United States
(12) Patent Application Publication
(10) Pub. No.: US 2007/0045717 A1
(43) Pub. Date: Mar. 1, 2007

(54) Charge-trapping memory device and method of production

(76) Inventors: Stefano Parascandola, Dresden (DE); Stephan Riedel, Dresden (DE)

Correspondence Address: SLATER & MATSIL LLP, 17950 PRESTON ROAD, SUITE 1000, DALLAS, TX, 75252, US

(21) Appl. No.: 11/216,525

(22) Filed: Aug. 31, 2005

(51) Int. Cl. H01L 29/792; H01L 21/336

(52) U.S. Cl. 257/324; 257/510; 257/637; 438/287; 438/435

(57) ABSTRACT

A plurality of parallel shallow trenches is etched at a main surface of a semiconductor substrate. A sequence of dielectric materials that are suitable for charge-trapping is applied on the whole surface including sidewalls and bottom surfaces of the etched trenches. This layer sequence completely fills the trenches and forms the shallow trench isolations. An additional layer can be provided between the memory layer and the top layer in order to achieve a planar upper surface.

### TECHNICAL FIELD

This invention relates generally to semiconductor devices and methods, and more particularly to a charge-trapping memory device and a method of production.

### BACKGROUND

Semiconductor memory devices include an array of memory cells that are arranged at a main surface of a semiconductor substrate. Rows of memory cells are electrically insulated from one another by shallow trench isolations that are produced in the substrate material by etching parallel trenches, which are subsequently filled with dielectric material.

Charge-trapping memory cells include a layer sequence of dielectric materials suitable for charge-trapping. Examples of charge-trapping memory cells are the SONOS memory cells comprising oxide-nitride-oxide layer sequences as storage medium.

U.S. Pat. Nos. 5,768,192 and 6,011,725, both of which are incorporated herein by reference, disclose charge-trapping memory cells of a special type of so-called NROM cells, which can be used to store bits of information both at the source and at the drain below the respective gate edges. NROM cells are usually programmed by channel hot electron injection. The programmed cell is read in reverse mode to achieve a sufficient two-bit separation. Erasure is performed by hot hole injection.

The charge-trapping layer sequence is usually applied on the main surface of the substrate after the formation of the shallow trench isolations. The effective channel width of NROM cells is highly affected by the final top width of the shallow trench isolations, the thickness of the charge-trapping layer sequence and the step height between the dielectric material of the shallow trench isolations and the adjacent semiconductor material of the substrate surface. There are numerous further single process steps by which the structure of the memory cell array and thus the performance of the memory are affected. Doping atoms that are implanted to adjust the threshold voltage of the memory cell transistors may diffuse from the semiconductor material into the dielectric material of the shallow trench isolations. This is regarded as a possible source of cell instability. A further miniaturization of the memory cells is expected to aggravate these problems.

### SUMMARY OF THE INVENTION

A shallow trench isolation structuring integration scheme is proposed, in which the effective channel width is mainly determined by the dimension of the active areas after the etching of the isolation trenches. This scheme is characterized by the application of the charge-trapping layer sequence after the structuring of the trenches that are provided for the shallow trench isolations and without a previous deposition of other dielectric material to fill the trenches. The application of a charge-trapping layer sequence also within the trenches has the additional advantage to prevent or at least inhibit an outdiffusion of implanted dopants from the cell channels into the dielectric material of the shallow trench isolations.

The charge-trapping memory device includes a semiconductor substrate, especially of silicon, having a main surface, in which a plurality of trenches provided for shallow trench isolations are etched. The etched trenches are arranged to separate rows or columns of memory cells of a memory cell array. The memory cells are provided with a charge-trapping layer sequence of dielectric materials that comprise at least one material that is suitable for charge-trapping. The charge-trapping layer sequence is arranged on the main surface of the semiconductor substrate, including the sidewalls and bottoms of the trenches, and fills the trenches, thus forming the shallow trench isolations.

The charge-trapping layer sequence comprises a bottom layer, which is conformal with the main surface of the substrate in the area of the memory cell array. This clearly defines the top width of the cell transistor bodies, i.e., the lateral dimension of the active areas, which are outlined by the shape of the bottom layer at the upper edges of the transistor bodies. Furthermore, the charge-trapping layer sequence, especially a memory layer that is applied on the bottom layer and is provided for charge-trapping, provides a diffusion barrier against a diffusion of semiconductor material into the shallow trench isolations. The charge-trapping layer sequence can for instance comprise a bottom layer of oxide, especially silicon oxide, a memory layer of nitride, especially silicon nitride, and a top layer of oxide, especially silicon oxide.

In a manufacturing method of embodiments of these charge-trapping memory devices, a plurality of trenches running parallel at a distance from one another is etched into a main surface of a semiconductor substrate, especially a silicon substrate. The location of the trenches can be defined by the openings of a hard mask, preferably a layer of silicon nitride that is structured in a usual way by means of a photolithography step. After the formation of the trenches, a charge-trapping layer sequence is applied, which can especially be an oxide-nitride-oxide-layer sequence. These layers can be grown or deposited. The layer sequence is applied in such a manner that the trenches are completely filled so that the shallow trench isolations are formed by the dielectric materials of the charge-trapping layer sequence. The dielectric materials can be selected to be suitable to prevent an outdiffusion of the implanted doping atoms. For this purpose, it is especially appropriate to apply a memory layer of nitride.

A variant of this method comprises an additional application of a further layer of the same material as the top layer of the charge-trapping layer sequence after the application of the memory layer and before the application of the top layer of the charge-trapping layer sequence. The further layer is provided to fill the trenches to an upper level of the memory layer. It is removed except for residual parts so that an essentially planar upper surface of the memory layer is achieved. Then the top layer of the charge-trapping layer sequence is deposited or grown.

These and other features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross section of a first intermediate product transversely to the etched trenches;

FIG. 2 shows the cross section according to FIG. 1 after the application of the bottom layer of the charge-trapping layer sequence;

FIG. 3 shows the cross section according to FIG. 2 after the application of the memory layer;

FIG. 4 shows the cross section according to FIG. 3 after the application of the top layer of the charge-trapping layer sequence;

FIG. 5 shows the cross section according to FIG. 4 of an alternative embodiment in which a further layer is applied onto the memory layer;

FIG. 6 shows the cross section according to FIG. 5 after a removal of the further layer essentially to the top level of the memory layer; and

FIG. 7 shows the cross section according to FIG. 6 after the application of the top layer of the charge-trapping layer sequence.

The following list of reference symbols can be used in conjunction with the figures:
1 substrate
2 trench
3 upper surface
4 sidewall and bottom surface
5 bottom layer
6 memory layer
7 top layer
8 further layer
9 residual part
10 top layer

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

FIG. 1 shows a cross section of a first intermediate product transversely to the isolation trenches. The semiconductor body 1, preferably of silicon, has a main surface, which is structured with etched trenches 2, which run parallel to one another at a distance from one another. This distance defines the bodies of the memory cell transistors. The semiconductor body 1 can be a substrate, e.g., monocrystalline silicon substrate, or a layer (e.g., silicon-on-insulator) or region above or within a substrate.

Between the trenches 2, there are areas of the upper surface 3 that form portions of the main surface of the substrate. These areas are the active areas of the memory cell array. The trenches have sidewalls and bottom surfaces 4.

The upper surface 3 and the sidewalls and bottom surfaces 4 of the trenches form the main surface of the substrate and are covered by a bottom layer 5 as shown in FIG. 2. The bottom layer 5 is provided as the first layer of the charge-trapping layer sequence. It is preferably oxide, especially silicon oxide (e.g., SiO₂), which can be grown or deposited.

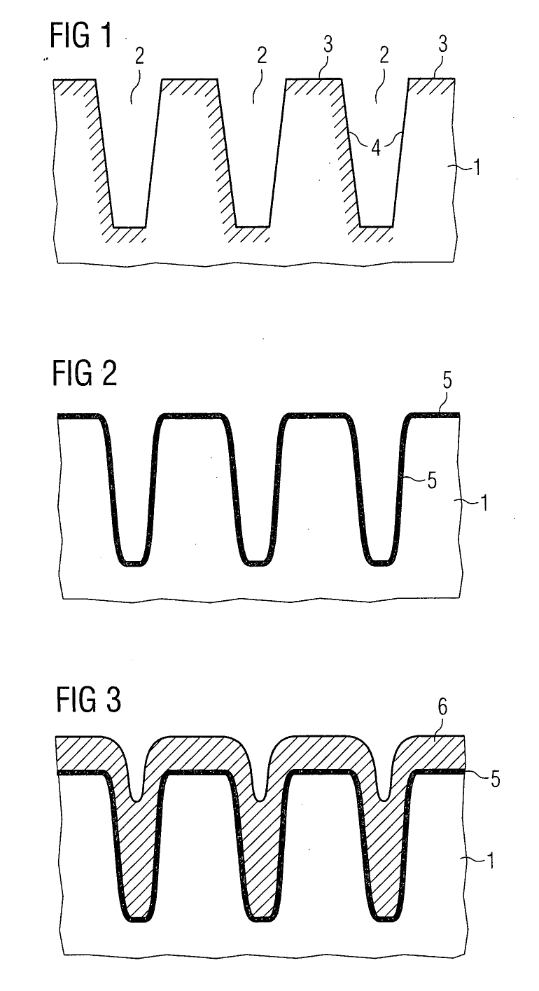

FIG. 3 shows the application of the memory layer 6 of the charge-trapping layer sequence onto the bottom layer 5. The memory layer 6 is preferably silicon nitride (e.g., Si₃N₄); but any other dielectric material that is suitable for charge-trapping can be applied here.

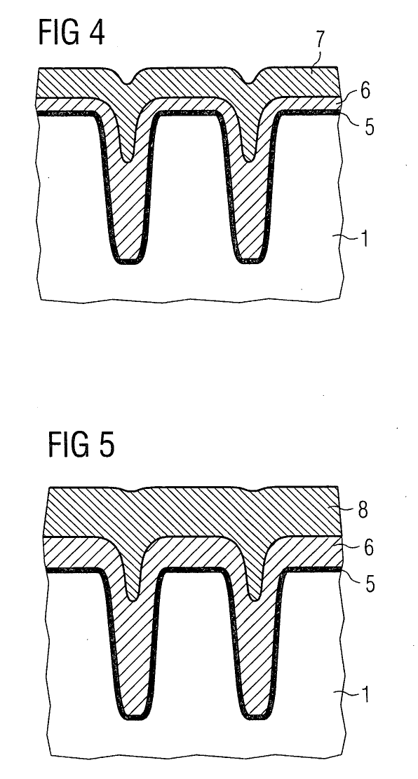

The charge-trapping layer sequence can then be completed by the application of the top layer 7 as shown in FIG. 4. The top layer 7 preferably comprises the same dielectric material as the bottom layer 5. If this method does not render a sufficiently planar upper surface, a further dielectric layer is preferably applied according to a further embodiment, which is described in the following.

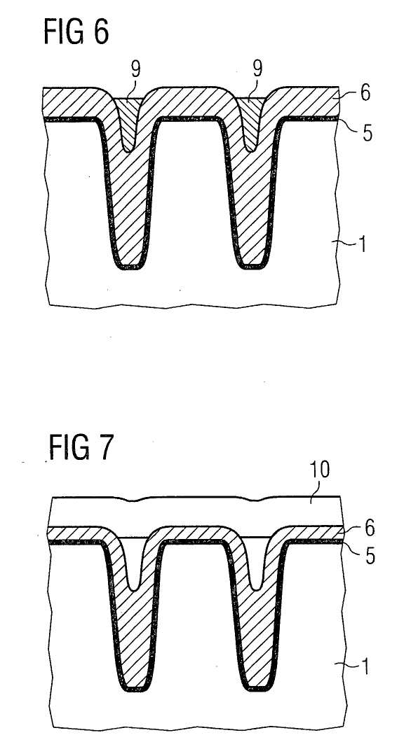

FIG. 5 shows the cross section according to FIG. 3 after the application of the further dielectric layer 8 before the application of the top layer. This further layer 8 is provided to fill the remaining openings in the trenches. It is removed essentially down to the top level of the memory layer 6 as shown in FIG. 6. The residual parts 9 of the further layer 8 essentially fill the remaining openings of the trenches left by the memory layer 6. Then the top layer 10 is applied according to FIG. 7. The sequence of the bottom layer, the memory layer and the top layer forms the charge-trapping layer sequence. The edges of the active areas and memory cell transistors are precisely defined by the bottom layer 5 which is conformal with the surface of the semiconductor material.

The trenches shown in FIG. 1 are preferably etched by means of a hard mask, which is applied to the upper surface of the substrate 1 and is structured by photolithography. Before this hard mask is removed, an additional wet etching step can be applied to modify the rounding of the upper edges of the transistor bodies. Alternatively, this can be done by an H₂ anneal. Instead, these process steps can be performed after the removal of the hard mask directly with the intermediate product shown in FIG. 1. The hard mask can also be used to apply a first thin oxide layer on the sidewalls and bottom surfaces of the trenches. This can be helpful to better adjust the thickness of the subsequently applied bottom layer. In this way, a relatively thin bottom layer of the charge-trapping layer sequence is obtained in the active areas, whereas the total layer thickness underneath the memory layer 6 is larger within the trenches so that a greater portion of the volume of the trenches is filled by this material.

The preferred embodiment of the invention uses the charge-trapping layer sequence as a diffusing barrier on the semiconductor material to prevent the outdiffusion of dopant atoms. The forming of the charge-trapping layer sequence within the trenches enables an especially precise width uniformity of the active areas. The process steps can be performed to produce a structure having an essentially planar upper surface without additional planarizing steps being necessary; and non-uniform structures like steps between the shallow trench isolations and the cell transistor bodies are avoided.

Although the present invention and its advantages have been described in detail, it should be understood that various changes, substitutions and alterations can be made herein without departing from the spirit and scope of the invention as defined by the appended claims.

What is claimed is:

1. A charge-trapping memory device comprising:
a semiconductor body having a main surface;
a plurality of shallow trench isolations at the main surface, the trench isolations each including a trench filled with a trench filling material;
an array of memory cells on the main surface; and
a charge-trapping layer sequence of dielectric materials, wherein the charge-trapping layer sequence is disposed on the main surface and wherein the trench filling material comprises the charge-trapping layer sequence.

2. The charge-trapping memory device as claimed in claim 1, wherein the charge-trapping layer sequence comprises a nitride layer provided as a memory layer.

3. The charge-trapping memory device as claimed in claim 2, wherein the charge-trapping layer sequence comprises a bottom oxide layer and a top oxide layer.

4. A charge-trapping memory device comprising:
a semiconductor substrate having a main surface;
a plurality of shallow trench isolations at the main surface, each shallow trench isolation including an isolation trench;
an array of memory cells on the main surface; and
a charge-trapping layer sequence of dielectric materials, wherein said charge-trapping layer sequence comprises a memory layer of a charge-trapping dielectric and also fills said isolation trenches.

5. The charge-trapping memory device as claimed in claim 4, wherein the charge-trapping layer sequence comprises a nitride layer provided as the memory layer.

6. The charge-trapping memory device as claimed in claim 5, wherein the charge-trapping layer sequence comprises a bottom oxide layer and a top oxide layer.

7. A charge-trapping memory device, comprising:
a semiconductor substrate having a main surface;
a plurality of shallow trench isolations at the main surface;
an array of memory cells at that main surface;
a charge-trapping layer sequence of dielectric materials comprising a bottom layer, wherein the bottom layer is conformal with an area of said main surface that is located underneath the shallow trench isolations.

8. The charge-trapping memory device as claimed in claim 7, wherein the charge-trapping layer sequence comprises a bottom oxide layer.

9. The charge-trapping memory device as claimed in claim 8, wherein the charge-trapping layer sequence further comprises a nitride layer provided as a memory layer and a top oxide layer.

10. A charge-trapping memory device, comprising:
a semiconductor substrate having a main surface;
a plurality of shallow trench isolations at the main surface, the shallow trench isolations separating active areas;
an array of memory cells at said main surface, the array comprising memory cell transistors that are disposed in the active areas; and
a charge-trapping layer sequence of dielectric materials comprising a bottom layer and a memory layer of a charge-trapping dielectric, the bottom layer covering the main surface of the semiconductor substrate, including areas of said main surface that are located underneath said shallow trench isolations, in an area of said array of memory cells and outlining a boundary between said active areas and said shallow trench isolations.

11. The charge-trapping memory device as claimed in claim 10, wherein the charge-trapping layer sequence comprises a bottom oxide layer, the charge-trapping layer sequence further comprising a nitride layer provided as a memory layer, and a top oxide layer.

12. A method for producing charge-trapping memory devices, the method comprising:
providing a semiconductor body with a main surface;
forming a plurality of trenches running parallel at a distance from one another at said main surface;
applying a dielectric material to form a bottom layer of a charge-trapping layer sequence;
applying a further dielectric material to form a memory layer of said charge-trapping layer sequence; and
applying a top layer of said charge-trapping layer sequence, wherein said charge-trapping layer sequence both fills said trenches and covers said main surface of said semiconductor body between said trenches.

13. The method as claimed in claim 12, wherein applying a dielectric material to form said bottom layer comprises growing or depositing an oxide that includes the same semiconductor material as said semiconductor body.

14. The method as claimed in claim 12, wherein applying a further dielectric material to form said memory layer comprises growing or depositing a nitride that includes the same semiconductor material as said semiconductor body.

15. The method as claimed in claim 12, further comprising, after applying a further dielectric material to form said memory layer, applying a further layer of the same material as the material that is provided for said top layer, and then applying the top layer.

16. The method as claimed in claim 15, wherein said top layer is applied by one of growing or depositing.

17. A method for producing charge-trapping memory devices, the method comprising:
providing a semiconductor body with a main surface;
forming a plurality of trenches at said main surface;
applying a dielectric material to form a bottom layer of a charge-trapping layer sequence;
applying a further dielectric material to form a memory layer of said charge-trapping layer sequence;
applying a further layer of a further dielectric material, thereby filling said trenches;
removing said further layer down to an upper level of said memory layer; and
applying a top layer of the same dielectric material as said further layer.

18. The method as claimed in claim 17, wherein the semiconductor body comprises a silicon body.

19. The method as claimed in claim 18, wherein applying a dielectric material to form said bottom layer comprises growing or depositing silicon oxide.

20. The method as claimed in claim 18, wherein applying a further dielectric material to form said memory layer comprises growing or depositing silicon nitride.
